(19) United States
(12) Patent Application Publication
(10) Pub. No.: US 2025/0255057 A1
(43) Pub. Date: Aug. 7, 2025

(54) Display Device

(71) Applicant: LG Display Co., Ltd., Seoul (KR)

(72) Inventors: SeungJun Lee, Paju-si (KR); Kiyong Yang, Seoul (KR); YongSeok Kwak, Paju-si (KR); Hyowon Kwon, Paju-si (KR)

(21) Appl. No.: 18/738,674

(22) Filed: Jun. 10, 2024

(30) Foreign Application Priority Data
Feb. 6, 2024 (KR) 10-2024-0018447

(51) Int. Cl. H01L 33/62; H01L 25/16; H01L 27/12; H01L 33/60

(52) U.S. Cl. CPC H10H 20/857; H01L 25/167; H10D 86/451; H10D 86/60; H10H 20/856

(57) ABSTRACT

A display device is disclosed that comprises a substrate and sub-pixels on the substrate that each include a first area and a second area is defined. The display device comprises a plurality of reflective electrodes on the substrate. The display device comprises a plurality of transistors in each of the plurality of sub-pixels on the substrate. The display device comprises a plurality of first light emitting diodes each in the first area of a corresponding sub-pixel. The display device comprises a second light emitting diode in the second area in at least one of the plurality of sub-pixels and is different from the plurality of first light emitting diodes. A bottom surface of the second light emitting diode and bottom surfaces of the plurality of first light emitting diodes are on different planes.

### CROSS-REFERENCE TO RELATED APPLICATION

This application claims the priority of Republic of Korea Patent Application No. 10-2024-0018447 filed on Feb. 6, 2024, in the Korean Intellectual Property Office, which is hereby incorporated by reference in its entirety.

### BACKGROUND

### Field

The present disclosure relates to a display device, and more particularly, to a display device using a light emitting diode (LED)

### Description of the Related Art

As display devices which are used for a monitor of a computer, a television, a cellular phone, or the like, there are an organic light emitting display (OLED) device which is a self-emitting device, a liquid crystal display (LCD) device which requires a separate light source, and the like.

An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast-lighting speed, excellent luminous efficiency, and a strong impact resistance so that a stability is excellent and an image having a high luminance can be displayed.

### SUMMARY

An object to be achieved by the present disclosure is to provide a display device with reduced process costs by transferring repair light emitting devices when defects occur.

Another object to be achieved by the present disclosure is to provide a display device capable of suppressing short circuit problems in a repair light emitting device.

Still another object to be achieved by the present disclosure is to provide a display device capable of stably performing a repair process.

Objects of the present disclosure are not limited to the above-mentioned objects, and other objects, which are not mentioned above, can be clearly understood by those skilled in the art from the following descriptions.

In one embodiment, a display device comprises: a substrate; a plurality of sub-pixels on the substrate, each sub-pixel including a first area and a second area; a plurality of reflective electrodes on the substrate; a plurality of transistors in each of the plurality of sub-pixels on the substrate; a plurality of first light emitting diodes, each first light emitting diode in the first area of a corresponding sub-pixel of the plurality of sub-pixels; and a second light emitting diode in the second area of at least one sub-pixel of the plurality of sub-pixels, wherein the second light emitting diode is different from the plurality of first light emitting diodes, and a bottom surface of the second light emitting diode and bottom surfaces of the plurality of first light emitting diodes are on different planes in a cross-section view of the display device.

In one embodiment, a display device comprises: a substrate; a sub-pixel on the substrate, the sub-pixel including a first area and a second area that is spaced apart from the first area; a transistor on the substrate; a light emitting diode in the first area, the light emitting diode including a first electrode and a second electrode; a first connection electrode connected to the first electrode of the light emitting diode in the first area, the first connection electrode electrically connecting the first electrode and the transistor; an additional connection electrode including a first portion of the additional connection electrode that is connected to the second electrode in the first area and a second portion that is in the second area at a height that is less than a height of the first portion of the additional connection electrode in the first area, the additional connection electrode electrically connecting together the second electrode of the light emitting diode and a power line; and a bank including a first portion of the bank in the first area, a second portion of the bank that is on the second portion of the additional connection electrode in the second area, and an opening overlapping the light emitting diode in the first area.

Other detailed matters of the exemplary embodiments are included in the detailed description and the drawings.

According to the present disclosure, it is possible to reduce the manufacturing costs of the display device by transferring the repair light emitting device when defects occur in a specific sub-pixel.

According to the present disclosure, it is possible to facilitate the repair of the light emitting device by forming a step structure on the lower portion of the electrode of the repair light emitting device.

According to the present disclosure, it is possible to suppress short circuit problems that may occur during the repair process by using the step structure of the contact hole.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic configuration diagram of a display device according to an exemplary embodiment of the present disclosure;

FIG. 2 is an enlarged plan view of a display device according to an exemplary embodiment of the present disclosure;

FIG. 3 is a cross-sectional view taken along line A-B of FIG. 2 according to an exemplary embodiment of the present disclosure;

FIG. 4 is an enlarged plan view of a display device before a repair process according to an exemplary embodiment of the present disclosure;

FIGS. 5A to 5C are diagrams for describing a repair process of a display device according to an exemplary embodiment of the present disclosure; and

FIG. 6 is a cross-sectional view of a display device according to another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

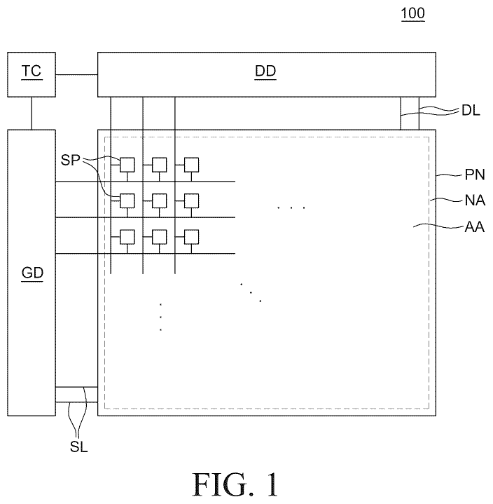

FIG. 1 is a schematic configuration diagram of a display device according to an exemplary embodiment of the present disclosure. For convenience of explanation, FIG. 1 illustrates only a display panel PN, a gate driver GD, a data driver DD, and a timing controller TC among various components of a display device 100.

Referring to FIG. 1, the display device 100 includes the display panel PN including a plurality of sub-pixels SP, the gate driver GD and the data driver DD that supply various signals to the display panel PN, and the timing controller TC that controls the gate driver GD and the data driver DD.

The gate driver GD supplies a plurality of scan signals to a plurality of scan lines SL according to a plurality of gate control signals provided from the timing controller TC. In FIG. 1, one gate driver GD is illustrated as being spaced apart from one side of the display panel PN, but the number and disposition of gate drivers GD are not limited thereto.

The data driver DD converts image data input from the timing controller TC into a data voltage using a reference gamma voltage according to a plurality of data control signals provided from the timing controller TC. The data driver DD may supply the converted data voltage to a plurality of data lines DL.

The timing controller TC sorts the image data input from the outside and supplies the sorted image data to the data driver DD. The timing controller TC may generate the gate control signal and the data control signal using a synchronization signal input from the outside, for example, a dot clock signal, a data enable signal, and a horizontal/vertical synchronization signal. The timing controller TC may supply the generated gate control signal and data control signal to the gate driver GD and the data driver DD, respectively, to control the gate driver GD and the data driver DD.

The display panel PN is a component for displaying images to a user, and includes the plurality of sub-pixels SP. In the display panel PN, a plurality of scan lines SL and the plurality of data lines DL intersect each other, and each of the plurality of sub-pixels SP is connected to the scan line SL and the data line DL. In addition, although not illustrated in the drawings, each of the plurality of sub-pixels SP may be connected to a high potential power line, a low potential power line, a reference line, etc.

A display area AA and a non-display area NA surrounding the display area AA may be defined in the display panel PN.

The display area AA is an area where an image is displayed on the display device 100. The plurality of sub-pixels SP constituting a plurality of pixels and a circuit for driving the plurality of sub-pixels SP may be disposed in the display area AA. The plurality of sub-pixels SP are a minimum unit that constitutes the display area AA, and n sub-pixels SP may form one pixel. A light emitting diode, a thin film transistor for driving the light emitting diode, or the like may be disposed in each of the plurality of sub-pixels SP. A plurality of light emitting diodes may be defined differently depending on a type of display panel PN. For example, when the display panel PN is an inorganic light emitting display panel, the light emitting diode may be a light-emitting diode (LED) or a micro light-emitting diode (micro-LED).

A plurality of signal lines that transmit various signals to the plurality of sub-pixels SP are disposed in the display area AA. For example, the plurality of signal lines may include the plurality of data lines DL through which a data voltage is supplied to each of the plurality of sub-pixels SP, the plurality of scan lines SL through which a gate voltage is supplied to each of the plurality of sub-pixels SP, etc. The plurality of scan lines SL may extend in one direction in the display area AA and may be connected to the plurality of sub-pixels SP, and the plurality of data lines DL may extend in a different direction from the one direction in the display area AA and may be connected to the plurality of sub-pixels SP. In addition, a low potential power line, a high potential power line, and the like may be further disposed in the display area AA, but are not limited thereto.

The non-display area NA is an area where an image is not displayed and may be defined as an area extending from the display area AA. Link lines and pad electrodes for transmitting signals to the sub-pixel SP of the display area AA, driver ICs such as gate driver ICs and data driver ICs, or the like may be disposed in the non-display area NA. The non-display area NA may be located on a rear surface of the display panel PN, that is, on a surface without the sub-pixel SP, or may be omitted, and is not limited to what is illustrated in the drawings.

Meanwhile, drivers such as the gate driver GD, the data driver DD, and the timing controller TC may be connected to the display panel PN in various ways. For example, the gate driver GD may be mounted in the non-display area NA in a gate in panel (GIP) manner or may be mounted between the plurality of sub-pixels SP in the gate in active area (GIA) manner in the display area AA. For example, the data driver DD and the timing controller TC may be formed on a separate flexible film and printed circuit board, and may be electrically connected to the display panel PN by bonding the flexible film and printed circuit board to the pad electrode formed in the non-display area NA of the display panel PN. When the gate driver GD is mounted in the GIP manner and the data driver DD and the timing controller TC transmit signals to the display panel PN through the pad electrode in the non-display area NA, an area of the non-display area NA may be secured to dispose the gate driver GD and the pad electrode and a bezel may increase.

In contrast, when the gate driver GD is mounted inside the display area AA in the GIA manner and a side wiring is formed to connect a signal line on a front surface of the display panel PN to a pad electrode on a rear surface of the display panel PN to bond the flexible film and printed circuit board to the rear surface of the display panel PN, the non-display area NA may be reduced to a minimum on the front surface of the display panel PN. That is, when the gate driver GD, the data driver DD, and the timing controller TC are connected to the display panel PN in the same manner as described above, it may be possible to implement a zero bezel in which there is substantially no bezel.

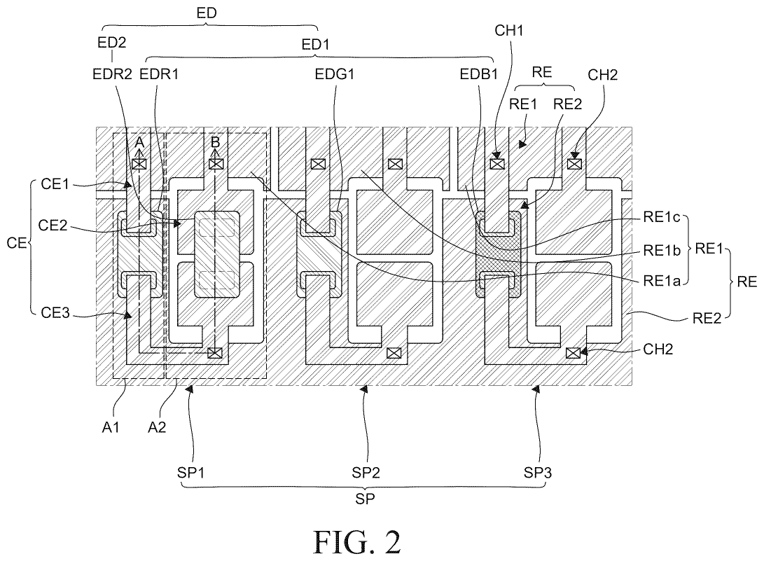

FIG. 2 is a schematic enlarged plan view of a display device according to an exemplary embodiment of the present disclosure. For convenience of illustration, FIG. 2 illustrates the plurality of sub-pixels SP, a plurality of reflective electrodes RE, a plurality of light emitting diodes ED, and a plurality of connection electrodes CE. FIG. 2 illustrates a case where since, among the plurality of sub-pixels SP, a first red light emitting diode EDR1 disposed in a first sub-pixel SP1 is defective and a first green light emitting diode EDG1 disposed in a second sub-pixel SP2 and a first blue light emitting diode EDB1 disposed in a third sub-pixel SP3 are normal, a repair process is performed on the first sub-pixel SP1. Here, the case where the light emitting diode is defective refers to the case where the light emitting diode is not lit (e.g., does not emit light) or is not lit normally since the light emitting diode itself is defective or the light emitting diode itself is not defective but an electrical connection between the light emitting diode and other components is defective.

First, referring to FIG. 2, the display panel PN includes a plurality of pixels composed of the plurality of sub-pixels SP. Each of the plurality of sub-pixels SP includes a light emitting diode ED and a pixel circuit, and thus, may emit light independently. One pixel may include one or more first sub-pixels SP1, one or more second sub-pixels SP2, and one or more third sub-pixels SP3. For example, the first sub-pixel SP1 may be a red sub-pixel, the second sub-pixel SP may be a green sub-pixel, and the third sub-pixel SP3 may be a blue sub-pixel, but the present disclosure is not limited thereto.

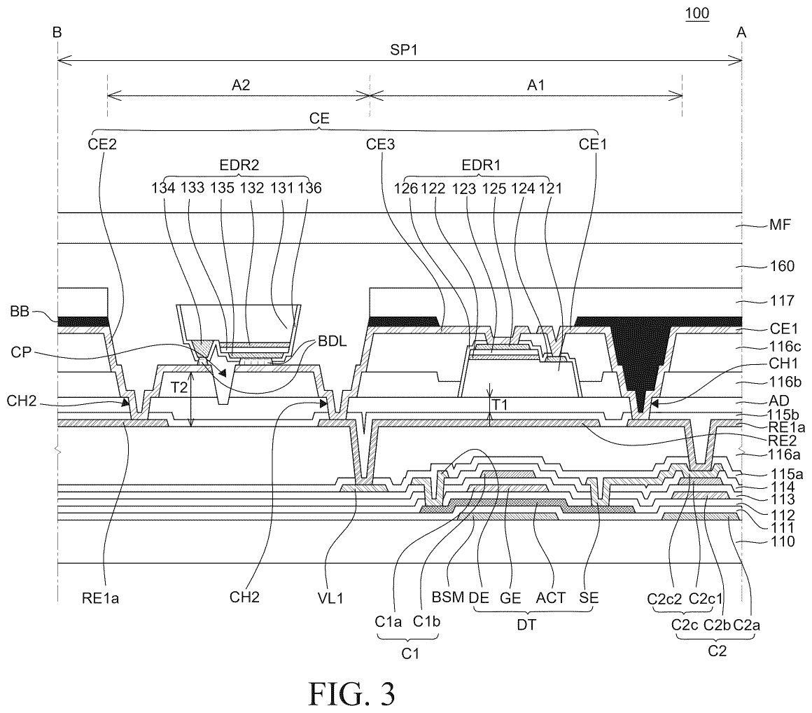

Each of the plurality of sub-pixels SP may include a first area A1 and a second area A2. Details of the first area A1 and the second area A2 are described below with reference to FIG. 3.

The plurality of reflective electrodes RE are disposed in the plurality of sub-pixels SP. The plurality of reflective electrodes RE may include a plurality of first reflective electrode RE1 and a plurality of second reflective electrode RE2.

The plurality of first reflective electrodes RE1 may include a 1-1-th reflective electrode RE1a, a 1-2-th reflective electrode RE1b, and a 1-3-th reflective electrode RE1c.

The 1-1-th reflective electrode RE1a may be disposed adjacent to the first sub-pixel SP1 among the plurality of sub-pixels SP. Accordingly, the 1-1-th reflective electrode RE1a may reflect light emitted from the first red light emitting diode EDR1 and the second red light emitting diode EDR2 to an upper portion of the 1-1-th reflective electrode RE1a.

The 1-2-th reflective electrode RE1b may be disposed adjacent to the second sub-pixel SP2 among the plurality of sub-pixels SP. Accordingly, when the second green light emitting diode is disposed in the second area A2 of the second sub-pixel SP2, the 1-2-th reflective electrode RE1b may reflect light emitted from the first green light emitting diode EDG1 and the second green light emitting diode to an upper portion of the 1-2-th reflective electrode RE1b.

The 1-3-th reflective electrode RE1c may be disposed adjacent to the third sub-pixel SP3 among the plurality of sub-pixels SP. Accordingly, when the second blue light emitting diode is disposed in the second area A2 of the third sub-pixel SP3, the 1-3-th reflective electrode RE1c may reflect light emitted from the first blue light emitting diode EDB1 and the second blue light emitting diode to an upper portion of the 1-3-th reflective electrode RE1c.

Each of the 1-1-th reflective electrode RE1a, 1-2-th reflective electrode RE1b, and 1-3-th reflective electrode RE1c may electrically connect a corresponding driving transistor to the plurality of light emitting diodes ED.

Meanwhile, the second reflective electrode RE2 may be disposed to overlap the plurality of sub-pixels SP. The second reflective electrode RE2 may be disposed to overlap all of the plurality of first light emitting diodes ED1, and may be disposed to non-overlap the second light emitting diode ED2. Referring to FIG. 2, the second reflective electrode RE2 may overlap the entire first red light emitting diode EDR1 and may not overlap the second red light emitting diode EDR2. Accordingly, the second reflective electrode RE2 may reflect light emitted from the plurality of first light emitting diodes ED1 to an upper portion of the second reflective electrode RE2.

However, the present disclosure is not limited thereto, and the second reflective electrode RE2 may be disposed to overlap the entire bottom surface of the second light emitting diode ED2 disposed in the second area A2 to reflect light emitted from the second light emitting diode ED2 to the upper portion of the second reflective electrode RE2.

The second reflective electrode RE2 may be disposed to be spaced apart from the plurality of first reflective electrode RE1. Referring to FIG. 2, when the first sub-pixel SP1, the second sub-pixel SP2 and the third sub-pixel SP3 are disposed along one direction, the second reflective electrode RE2 may be disposed to extend along the direction in which the first sub-pixel SP1, the second sub-pixel SP2, and the third sub-pixel SP3 are disposed, but is not limited thereto.

The second reflective electrode RE2 may electrically connect a plurality of power lines VL1 to the plurality of light emitting diodes ED.

A plurality of connection electrodes CE are disposed on the plurality of reflective electrodes RE. The plurality of connection electrodes CE may be disposed in each of the plurality of sub-pixels SP to electrically connect the plurality of reflective electrodes RE to the plurality of first light emitting diodes ED1 and the second light emitting diodes ED2.

The plurality of connection electrodes CE includes a first connection electrode CE1, a second connection electrode CE2, and a third connection electrode CE3 in one embodiment.

Each of the first connection electrode CE1 and the second connection electrode CE2 may electrically connect a plurality of first light emitting diode ED1 and second light emitting diodes ED2 to each of the plurality of first reflective electrodes RE1. The third connection electrode CE3 may electrically connect the plurality of first light emitting diodes ED1 to second light emitting diodes ED2. Therefore, the third connection electrode CE3 may be referred to as an additional connection electrode.

Meanwhile, the second connection electrode CE2 and the third connection electrode CE3 may be designed considering the electrical characteristics of the second light emitting diode ED2. For example, the second connection electrode CE2 and the third connection electrode CE3 may have a width wider than a width of the first connection electrode CE1 in the area overlapping with the second light emitting diode ED2 in the second area A2. Accordingly, the electrical characteristics of the second connection electrode CE2, the third connection electrode CE3, and the second light emitting diode ED2 may be improved, but the present disclosure is not limited thereto.

Details of the plurality of connection electrodes CE will be described below with reference to FIG. 3.

The plurality of light emitting diodes ED including the plurality of first light emitting diodes ED1 and the plurality of second light emitting diodes ED2 may be disposed in the first area A1 and the second area A2.

The first light emitting diode ED1 among the plurality of light emitting diodes ED is disposed in the first area A1 of the plurality of sub-pixels SP.

The plurality of first light emitting diodes ED1 are the light emitting diodes ED that are first transferred onto the substrate during the manufacturing of the display device. That is, regardless of whether the plurality of first light emitting diodes ED1 are defective, the plurality of first light emitting diodes ED1 are disposed in each of the plurality of sub-pixels SP. Accordingly, the first light emitting diode ED1 may be referred to as a main light emitting diode.

The plurality of first light emitting diodes ED1 includes the first red light emitting diode EDR1, the first green light emitting diode EDG1, and the first blue light emitting diode EDB1. The first red light emitting diode EDR1 may be disposed in the first sub-pixel SP1, the first green light emitting diode EDG1 may be disposed in the second sub-pixel SP2, and the first blue light emitting diode EDB1 may be disposed in the third sub-pixel SP3.

The second light emitting diode ED2 among the plurality of light emitting diodes ED is disposed in the second area A2 of the plurality of sub-pixels SP. The second light emitting diode is the light emitting diode that is transferred onto the substrate when the first light emitting diode EDR1 disposed in the sub-pixel of the ED2 is defective. Accordingly, the second light emitting diode ED2 may be referred to as a repair light emitting diode.

As described above, when the first red light emitting diode EDR1 disposed in the first sub-pixel SP1 is defective, the second light emitting diode ED2 may include the second red light emitting diode EDR2. Accordingly, the second red light emitting diode EDR2 may be disposed in the first sub-pixel SP1, but the second light emitting diode ED2 may not be disposed in the second sub-pixel SP2 and the third sub-pixel SP3. However, the present disclosure is not limited thereto, and when the first green light emitting diode EDG1 disposed in the second sub-pixel SP2 is defective, the second light emitting diode ED2 may include the second green light emitting diode disposed in the second sub-pixel SP2. In addition, when the first blue light emitting diode EDB1 disposed in the third sub-pixel SP3 is defective, the second light emitting diode ED2 may include the second blue light emitting diode disposed in the third sub-pixel SP3.

Meanwhile, the second light emitting diode ED2 may have a different structure from the plurality of first light emitting diodes ED1. For example, the second light emitting diode ED2 may have a structure that is the reversed structure of the first light emitting diode ED1. That is, the first light emitting diode ED1 and the second light emitting diode ED2 have the same configuration, but in the cross section, the stacking order of the second light emitting diode ED2 may be opposite to the stacking order of the first light emitting diode ED1. In addition, the bottom surface of the second light emitting diode ED2 and the bottom surfaces of the plurality of first light emitting diodes ED1 may be disposed on different planes in the cross-section view of the display device.

Meanwhile, although not illustrated in FIG. 2, a driving transistor DT may be disposed in each of the first sub-pixel SP1, the second sub-pixel SP2, and the third sub-pixel SP3. For example, the driving transistor DT may include a first driving transistor disposed in the first sub-pixel SP1, a second driving transistor disposed in the second sub-pixel SP2, and a third driving transistor disposed in the third sub-pixel SP3.

In this case, when both the first light emitting diode ED1 and the second light emitting diode ED2 are disposed in one sub-pixel SP, the first light emitting diode ED1 and the second light emitting diode ED2 may be connected to the same driving transistor. Accordingly, among the plurality of light emitting diodes ED, the light emitting diode ED disposed in the same sub-pixel SP may be driven by the same driving transistor.

However, the present disclosure is not limited thereto, and a plurality of first driving transistors may be disposed in the first sub-pixel SP1, a plurality of second driving transistors may be disposed in the second sub-pixel SP2, and a plurality of third driving transistors may be disposed in the third sub-pixel SP3, so, among the plurality of light emitting diodes ED, the first light emitting diode ED1 and the second light emitting diode ED2 disposed in the same sub-pixel SP may be driven by different transistors.

Hereinafter, FIG. 3 will be referred to for a more detailed description of the first light emitting diode ED1 and the second light emitting diode ED2.

FIG. 3 is a cross-sectional view taken along line A-B of FIG. 2 according to one embodiment. Referring to FIG. 3, a light blocking layer BSM, a driving transistor DT, a first capacitor C1, a second capacitor C2, a plurality of reflective electrodes RE, a plurality of light emitting diodes ED, a plurality of connection electrodes CE, a plurality of bonding layers BDL, a plurality of power lines VL1, a bank BB, a fourth planarization layer 117, a protective layer 160, and an optical film MF may be disposed in each of the plurality of sub-pixels SP of the display device 100 according to an exemplary embodiment of the present disclosure.

Among insulating layers disposed on the substrate 110, a plurality of inorganic insulating layers may include a buffer layer 111, a gate insulating layer 112, a first interlayer insulating layer 113, a second interlayer insulating layer 114, and a first passivation layer 115a, and a second passivation layer 115b.

In addition, among the insulating layers disposed on the substrate 110, a plurality of organic insulating layers may include a planarization layer 116a, an adhesive layer AD, a second planarization layer 116b, and a third planarization layer 116c.

First, the substrate 110 is configured to support various components included in the display device 100, and may be formed of an insulating material. For example, the substrate 110 may be formed of glass, resin, or the like. In addition, the substrate 110 may formed of polymer or plastic, or may be formed of a material with flexibility.

Referring to FIG. 3, the light blocking layer BSM is disposed on the substrate 110. The light blocking layer BSM may minimize or at least reduce a leakage current by blocking light incident on active layers ACT of a plurality of transistors. For example, the light blocking layer BSM may be disposed below the active layer ACT of the driving transistor DT to block light incident on the active layer ACT. When light is irradiated to the active layer ACT, the leakage current may occur to decrease the reliability of the transistor. Therefore, the light blocking layer BSM blocking light may be disposed on the substrate 110 to improve the reliability of the driving transistor DT. The light blocking layer BSM may be formed of an opaque conductive material, such as copper (Cu), aluminum (Al), molybdenum (Mo), nickel (Ni), titanium (Ti), chromium (Cr), or an alloy thereof, but is not limited thereto.

The buffer layer 111 is disposed on the light blocking layer BSM. The buffer layer 111 is an inorganic insulating layer that may reduce the penetration of moisture or impurities through the substrate 110. The buffer layer 111 may be configured by, for example, a single layer or a duplex layer of silicon oxide (SiOx) or silicon nitride (SiNx), but is not limited thereto. However, the buffer layer 111 may be omitted depending on the type of substrate 110 or the type of thin film transistor, but is not limited thereto.

The driving transistor DT including the active layer ACT, a gate electrode GE, a source electrode SE, and a drain electrode DE is disposed on the buffer layer 111.

Meanwhile, although not illustrated in FIG. 3, an additional buffer layer may be disposed between the substrate 110 and the light blocking layer BSM. The additional buffer layer is an inorganic insulating layer that may reduce the penetration of moisture or impurities through the substrate 110 in the same way as the buffer layer 111 described above, and may be configured by a single layer or a duplex layer of silicon oxide (SiOx) or silicon nitride (SiNx), but is not limited thereto.

First, the active layer ACT of the driving transistor DT is disposed on the buffer layer 111. The active layer ACT may be formed of a semiconductor material such as oxide semiconductor, amorphous silicon, or polysilicon, but is not limited thereto. In addition, although not illustrated in the drawings, in addition to the driving transistor DT, other transistors, such as a switching transistor, a sensing transistor, an emission control transistor, may be in addition disposed, and the active layer of these transistors may also be formed of semiconductor materials such as oxide semiconductor, amorphous silicon, or polysilicon, but the present disclosure is not limited thereto. In addition, the active layers of the transistors included in the pixel circuit, such as the driving transistor DT, the switching transistor, the sensing transistor, and the emission control transistor may be formed of the same material or may be formed of different materials.

A gate insulating layer 112 is disposed on the active layer ACT. The gate insulating layer 112 is an inorganic insulating layer for electrically insulating the active layer ACT and the gate electrode GE, and may be configured by a single layer or a duplex layer of silicon oxide (SiOx) or silicon nitride (SiNx), but is not limited thereto.

The gate electrode GE is disposed on the gate insulating layer 112. The gate electrode GE may be formed of a conductive material, such as copper (Cu), aluminum (Al), molybdenum (Mo), nickel (Ni), titanium (Ti), chromium (Cr), or an alloy thereof, but is not limited thereto.

A first interlayer insulating layer 113 and a second interlayer insulating layer 114 are disposed on the gate electrode GE. Contact holes are formed in the first interlayer insulating layer 113 and the second interlayer insulating layer 114 for connecting the source electrode SE and the drain electrode DE, respectively, to the active layer ACT. The first interlayer insulating layer 113 and the second interlayer insulating layer 114 may be configured by an inorganic insulating layer to protect components below the first interlayer insulating layer 113 and the second interlayer insulating layer 114 and may be configured by a single layer or a duplex layer of silicon oxide (SiOx) or silicon nitride (SiNx), but are not limited thereto.

The source electrode SE and the drain electrode DE, which are electrically connected to the active layer ACT, are disposed on the second interlayer insulating layer 114. The source electrode SE is connected to the second capacitor C2 and a first electrode 124 of the light emitting diode ED, and the drain electrode DE is connected to other components of the pixel circuit. The source electrode SE and the drain electrode DE may be formed of a conductive material, such as copper (Cu), aluminum (Al), molybdenum (Mo), nickel (Ni), titanium (Ti), chromium (Cr), or an alloy thereof, but are not limited thereto.

The plurality of power lines VL1 are disposed on the second interlayer insulating layer 114. The plurality of power lines VL1 may transmit a power voltage to the light emitting diode ED of each of the plurality of sub-pixels SP. For example, the plurality of power lines VL1 may transmit a high potential power voltage or a low potential power voltage. The plurality of power lines VL1 may be formed of a conductive material, such as copper (Cu), aluminum (Al), molybdenum (Mo), nickel (Ni), titanium (Ti), chromium (Cr), or an alloy thereof, but are not limited thereto.

Next, the first capacitor C1 is disposed on the gate insulating layer 112. The first capacitor C1 includes a 1-1-th capacitor electrode C1a (e.g., a first capacitor electrode) and a 1-2-th capacitor electrode C1b (e.g., a second capacitor electrode).

First, the 1-1-th capacitor electrode C1a is disposed on the gate insulating layer 112. The 1-1-th capacitor electrode C1a may be integrated with the gate electrode GE of the driving transistor DT.

The 1-2-th capacitor electrode C1b is disposed on the first interlayer insulating layer 113. The 1-2-th capacitor electrode C1b is disposed to overlap the 1-1-th capacitor electrode C1a with the first interlayer insulating layer 113 interposed therebetween.

Accordingly, the first capacitor C1 may be connected to the gate electrode GE of the driving transistor DT, and may maintain the voltage of the gate electrode GE of the driving transistor DT for a certain period of time.

Next, the second capacitor C2 is disposed on the substrate 110. The second capacitor C2 includes a 2-1-th capacitor electrode C2a (e.g., a first capacitor electrode), a 2-2-th capacitor electrode C2b (e.g., a second capacitor electrode), and a 2-3-th capacitor electrode C2c (e.g., a third capacitor electrode). The second capacitor C2 includes the 2-1-th capacitor electrode C2a that is a lower capacitor electrode, the 2-2-th capacitor electrode C2b that is an intermediate capacitor electrode, and the 2-3-th capacitor electrode C2c that is an upper capacitor electrode.

The 2-1-th capacitor electrode C2a is disposed on the substrate 110. The 2-1-th capacitor electrode C2a is disposed on the same layer as the light blocking layer BSM and may be formed of the same material.

The 2-2-th capacitor electrode C2b is disposed on the buffer layer 111 and the gate insulating layer 112. The 2-2-th capacitor electrode C2b is disposed on the same layer as the gate electrode GE and may be formed of the same material.

The 2-3-th capacitor electrode C2c is disposed on the first interlayer insulating layer 113. The 2-3-th capacitor electrode C2c may be configured by a first layer C2c 1 and a second layer C2c2. The first layer C2cl of the 2-3-th capacitor electrode C2c may be formed of the same material in the same layer as the 1-2-th capacitor electrode C1b. The first layer C2cl may be disposed to overlap the 2-1-th capacitor electrode C2a and the 2-2-th capacitor electrode C2b with the first interlayer insulating layer 113 interposed therebetween.

The second layer C2c2 of the 2-3-th capacitor electrode C2c is disposed on the second interlayer insulating layer 114. The second layer C2c2 is a part extending from the source electrode SE of the driving transistor DT and may be connected to the first layer C2cl through the contact hole in the second interlayer insulating layer 114.

Therefore, the second capacitor C2 is electrically connected between the source electrode SE of the driving transistor DT and the light emitting diode ED, so the capacitance inherent in the light emitting diode ED may increase and light with higher brightness may be emitted from the light emitting diode ED.

The first passivation layer 115a is disposed on the driving transistor DT, the first capacitor C1, and the second capacitor C2. A first passivation layer 115a is an inorganic insulating layer to protect components below the first passivation layer 115a, and may be formed of inorganic materials such as silicon oxide (SiOx) or silicon nitride (SiNx), but is not limited thereto.

The first planarization layer 116a is disposed on the first passivation layer 115a. The first planarization layer 116a may planarize an upper portion of the pixel circuit including the driving transistor DT. The first planarization layer 116a may be configured by a single layer or a duplex layer, and may be formed of, for example, a benzocyclobutene or an acrylic-based organic insulating layer.

Referring to FIG. 3, the plurality of reflective electrodes RE are disposed on the first planarization layer 116a. The plurality of reflective electrodes RE may serve as a reflector that reflects the light emitted from the plurality of light emitting diodes ED to the upper portion of the substrate 110 while electrically connecting the plurality of light emitting diodes ED to the plurality of power lines VL1 and the driving transistor DT. The plurality of reflective electrodes RE are formed of a conductive material with excellent reflective properties, and may reflect the light emitted from the light emitting diode ED to the upper portion of the light emitting diode ED.

The reflective electrode RE may include various conductive layers in consideration of light reflection efficiency and resistance. For example, the reflective electrode RE may be configured by the opaque conductive layer such as silver (Ag), aluminum (Al), molybdenum (Mo), titanium (Ti), or an alloy thereof, along with a transparent conductive layer such as indium tin oxide (ITO). However, the structure of the reflective electrode RE is not limited thereto.

The reflective electrode RE may include a plurality of first reflective electrode RE1 and a second reflective electrode RE2 disposed to be spaced apart from the plurality of first reflective electrode RE1.

The plurality of first reflective electrode RE1 may be disposed in an area adjacent to the plurality of sub-pixels SP to reflect the light emitted from the plurality of light emitting diodes ED to the upper portion of the plurality of first reflective electrode RE1.

The plurality of first reflective electrodes RE1 may include the 1-1-th reflective electrode RE1a, the 1-2-th reflective electrode RE1b, and the 1-3-th reflective electrode RE1c.

The 1-1-th reflective electrode RE1a, the 1-2-th reflective electrode RE1b, and the 1-3-th reflective electrode RE1c may each be connected to the source electrode SE or the drain electrode DE of the driving transistor DT through the contact hole formed in the first planarization layer 116a, and may also be electrically connected to the plurality of separate light emitting diodes ED. For example, as illustrated in FIG. 3, the 1-1-th reflective electrode RE1a, the 1-2-th reflective electrode RE1b, and the 1-3-th reflective electrode RE1c may be connected to the source electrode SE of the driving transistor DT, but are not limited thereto.

First, the 1-1-th reflective electrode RE1a, the 1-2-th reflective electrode RE1b, and the 1-3-th reflective electrode RE1c may each be connected to the plurality of first light emitting diodes ED1 and the second light emitting diode ED2 through the plurality of connection electrodes CE. For example, referring to FIG. 3, the 1-1-th reflective electrode RE1a may be electrically connected to the first electrode 124 and the first semiconductor layer 121 of the first red light emitting diode EDR1 through the first connection electrode CE1 in the first sub-pixel SP1, and may be electrically connected to the first electrode 134 and a first semiconductor layer 131 of the second red light emitting diode EDR2 through the second connection electrode CE2.

Next, among the plurality of reflective electrodes RE, the second reflective electrode RE2 may reflect the light emitted from the light emitting diode ED to the upper portion of the second reflective electrode RE2.

The second reflective electrode RE2 may electrically connect the plurality of power lines VL1 to the plurality of light emitting diodes ED. The second reflective electrode RE2 may be connected to the plurality of power lines VL1 through the contact holes formed in the first planarization layer 116a and the first passivation layer 115a. In addition, the second reflective electrode RE2 may be electrically connected to the second electrode and the second semiconductor layer of the plurality of first light emitting diode ED1 through the plurality of connection electrodes CE, and may be electrically connected to the second electrode and the second semiconductor layer of the second light emitting diode ED2. For example, referring to FIG. 3, the second reflective electrode RE2 may be electrically connected to the second electrode 125 and the second semiconductor layer 123 of the first red light emitting diode EDR1 through the third connection electrode CE3, and may be electrically connected to a second electrode 135 and a second semiconductor layer 133 of the second red light emitting diode EDR2.

Meanwhile, all of the plurality of light emitting diodes ED may be separately connected to the plurality of power lines VL1 without being connected to the reflective electrode RE, but are not limited thereto.

Referring to FIG. 3, the second passivation layer 115b is disposed on the plurality of reflective electrodes RE. The second passivation layer 115b is the inorganic insulating layer to protect components below the second passivation layer 115b, and may be configured by a single layer or a duplex layer of silicon oxide (SiOx) or silicon nitride (SiNx), but is not limited thereto.

The plurality of contact holes may be disposed in the second passivation layer 115b to connect the plurality of connection electrodes CE to the plurality of reflective electrodes RE. Accordingly, the second passivation layer 115b may expose the top surfaces of the plurality of reflective electrodes RE in the area where the plurality of contact holes are disposed.

Referring to FIGS. 2 and 3, the plurality of contact holes may include a first contact hole CH1 and a plurality of second contact holes CH2.

The first contact hole CH1 is disposed in the first area A1. Referring to FIG. 3, the second passivation layer 115b may expose the top surfaces of the plurality of first reflective electrodes RE1 in the first contact hole CH1 disposed in the first area A1. In the first contact hole CH1, each of the plurality of first light emitting diodes ED1 and each of the plurality of driving transistors DT may be electrically connected through the plurality of first reflective electrode RE1.

The plurality of second contact holes CH2 are disposed in the second area A2. Referring to FIG. 3, the second passivation layer 115b may expose the top surfaces of the first reflective electrode RE1 and the second reflective electrode RE2 in the second contact hole CH2 disposed in the second area A2. The plurality of second light emitting diode ED2 and the first reflective electrode RE1, and the second reflective electrode RE2 may be electrically connected in the plurality of second contact holes CH2. For example, in one of the plurality of second contact holes CH2, the plurality of second light emitting diodes ED2 and the driving transistor DT may be electrically connected, and in the other of the plurality of second contact holes CH2, the plurality of second light emitting diodes ED2 and the plurality of power lines VL1 may be electrically connected.

Meanwhile, the plurality of second contact holes CH2 may be disposed at both end portions of the second area A2. For example, the plurality of second contact holes CH2 may expose the top surface of the first reflective electrode RE1 and the top surface of the second reflective electrode RE2 disposed at both end portions of the second area A2. In addition, the plurality of second contact holes CH2 may be disposed outside the second light emitting diode ED2 and may be disposed to face each other with the second light emitting diode ED2 interposed therebetween. The plurality of second contact holes CH2 may be disposed on both sides with the concave pattern CP interposed therebetween, but are not limited thereto.

The adhesive layer AD is disposed on the second passivation layer 115b. The adhesive layer AD is formed on the front surface of the substrate 110 and may fix (e.., attach) the light emitting diode ED disposed on the adhesive layer AD. The adhesive layer AD may be configured by an organic insulating layer. The adhesive layer AD may be formed of a photocurable adhesive material that may be cured by light. For example, the adhesive layer AD may be formed of an acrylic-based material containing a photosensitizer, but is not limited thereto.

The adhesive layer AD may planarize the upper portion of the plurality of reflective electrodes RE. For example, the adhesive layer AD may cover between the plurality of reflective electrodes RE disposed apart from each other and may planarize the upper portion of the plurality of reflective electrodes RE, but is not limited thereto.

In the adhesive layer AD, the first contact hole CH1 and the plurality of second contact holes CH2 may be disposed to connect the plurality of connection electrodes CE to the plurality of reflective electrodes RE. Accordingly, the adhesive layer AD may expose the top surfaces of the plurality of reflective electrodes RE in the first contact hole CH1 and the plurality of second contact holes CH2.

Meanwhile, the adhesive layer AD may have the concave pattern CP in the second area A2. The concave pattern CP is disposed in a structure with a step in the lower portion of the second light emitting diode ED2.

Meanwhile, FIG. 3 illustrates that the adhesive layer AD is disposed with a relatively thin thickness in the concave pattern CP of the second area A2, but the present disclosure is not limited thereto, and the adhesive layer AD may not be disposed in the concave pattern CP. For example, the adhesive layer AD may be disposed only in the area excluding the concave pattern CP in second area A2. That is, the concave pattern CP is through an entire thickness of the second planarization layer 116b and through a portion of the adhesive layer AD in the second area A2 such that a depth of the concave pattern CP is less than the thickness of the second planarization layer 116b and the adhesive layer AD in the second area A2.

The concave pattern CP may be disposed in an area that overlaps the second light emitting diode ED2. For example, referring to FIG. 3, the concave pattern CP may be disposed between the first electrode 134 and the second electrode 135 of the second red light emitting diode EDR2 in the second area A2.

Referring to FIGS. 2 and 3, the plurality of light emitting diodes ED are disposed in each of the plurality of sub-pixels SP on the adhesive layer AD.

The first light emitting diode ED1 among the plurality of light emitting diodes ED is disposed in each first area A1 of the plurality of sub-pixels SP.

Each of the plurality of first light emitting diodes ED1 includes a first semiconductor layer, a light emitting layer, a second semiconductor layer, a first electrode, a second electrode, and an encapsulation film. For example, referring to FIG. 3, the first red light emitting diode EDR1 may include the first semiconductor layer 121, the light emitting layer 122, the second semiconductor layer 123, the first electrode 124, the second electrode 125, and an encapsulation film 126.

Hereinafter, the description will be made on the assumption that the plurality of first light emitting diodes ED1 have a horizontal structure, but the type of the plurality of first light emitting diodes ED1 is not limited thereto.

The first semiconductor layer 121 of the first red light emitting diode EDR1 is disposed on the adhesive layer AD, and the second semiconductor layer 123 is disposed on the first semiconductor layer 121. The first semiconductor layer 121 and the second semiconductor layer 123 may be layers formed by doping n-type and p-type impurities into a specific material. For example, the first semiconductor layer 121 and the second semiconductor layer 123 may each be layers doped with n-type and p-type impurities in materials such as gallium nitride (GaN), indium aluminum phosphide (InAlP), and gallium arsenide (GaAs). In addition, the p-type impurities may be magnesium, zinc (Zn), beryllium (Be), or the like, and the n-type impurities may be silicon (Si), germanium, tin (Sn), or the like, but the present disclosure is not limited thereto.

The light emitting layer 122 is disposed between the first semiconductor layer 121 and the second semiconductor layer 123. The light emitting layer 122 may emit light by receiving holes and electrons from the first semiconductor layer 121 and the second semiconductor layer 123. The light emitting layer 122 may be formed of a single-layer or multi-quantum well (MQW) structure, and may be formed of, for example, indium gallium nitride (InGaN), gallium nitride (GaN), or the like, but is not limited thereto.

The light emitting layer 122 and the second semiconductor layer 123 of the first red light emitting diode EDR1 may be disposed to protrude upward from the top surface of the first semiconductor layer 121.

The first electrode 124 of the first red light emitting diode EDR1 is disposed on the first semiconductor layer 121. The first electrode 124 is an electrode for electrically connecting the driving transistor DT to the first semiconductor layer 121. In this case, the first semiconductor layer 121 may be a semiconductor layer doped with n-type impurities, and the first electrode 124 may be a cathode. The first electrode 124 may be disposed on the top surface of the first semiconductor layer 121 exposed from the light emitting layer 122 and the second semiconductor layer 123.

The first electrode 124 may be formed of a conductive material, for example, a transparent conductive material such as indium tin oxide (ITO) or indium zinc oxide (IZO), an opaque conductive material such as titanium (Ti), gold (Au), silver (Ag), copper (Cu), an alloy thereof, or the like, but is not limited thereto.

The second electrode 125 of the first red light emitting diode EDR1 is disposed on the second semiconductor layer 123. The second electrode 125 may be in contact with the top surface of the second semiconductor layer 123. The second electrode 125 is an electrode for electrically connecting the plurality of power lines VL1 to the second semiconductor layer 123. In this case, the second semiconductor layer 123 may be a semiconductor layer doped with p-type impurities, and the second electrode 125 may be an anode.

The second electrode 125 may be formed of a conductive material, for example, a transparent conductive material such as indium tin oxide (ITO) or indium zinc oxide (IZO), an opaque conductive material such as titanium (Ti), gold (Au), silver (Ag), copper (Cu), an alloy thereof, or the like, but is not limited thereto.

Next, the encapsulation film 126 surrounding the first semiconductor layer 121, the light emitting layer 122, the second semiconductor layer 123, the first electrode 124, and the second electrode 125 is disposed. The encapsulation film 126 is formed of an insulating material and may protect the first semiconductor layer 121, the light emitting layer 122, and the second semiconductor layer 123. In addition, the contact hole exposing the first electrode 124 and the second electrode 125 is formed in the encapsulation film 126, so the first connection electrode CE1 and the third connection electrode CE3 and the first electrode 124 and the second electrode 125 may be electrically connected.

Next, the second planarization layer 116b and the third planarization layer 116c are disposed on the adhesive layer AD.

The second planarization layer 116b may be disposed to surround side surface portions of the plurality of first light emitting diodes ED1 in the first area A1 to fix (e.g., attach) and protect the plurality of first light emitting diodes ED1. For example, the second planarization layer 116b may be disposed to surround lower side surfaces of the plurality of first light emitting diodes ED1 in the first area A1.

The second planarization layer 116b may be configured by a single layer or a duplex layer, and may be formed of, for example, a benzocyclobutene or an acrylic-based organic insulating layer. The second planarization layer 116b may be formed using a halftone mask. In the second planarization layer 116b, the portion disposed relatively adjacent to the first light emitting diode ED1 may be formed to have a relatively thin thickness, and the portion disposed relatively far from the first light emitting diode ED1 may be formed to have a relatively thick thickness.

The second planarization layer 116b may cover the side surfaces of the plurality of first light emitting diodes ED1 and suppress the contact and short circuit defects between the plurality of connection electrodes CE and the first light emitting diode ED1.

The second planarization layer 116b may cover the top surface of the adhesive layer AD in the second area A2.

Meanwhile, in the first area A1, the first light emitting diode ED1 may be disposed on the same layer as the second planarization layer 116b, but in the second area A2, the second light emitting diode ED2 may be disposed above the second planarization layer 116b. Accordingly, the bottom surface of the second light emitting diode ED2 may be disposed at a higher position than the bottom surface of the first light emitting diode ED1 as much as the thickness of the second planarization layer 116b. That is, a height of the bottommost surface of the second light emitting diode ED2 is higher than a height of the bottommost surface of the first light emitting diode ED1.

For example, the thickness of second passivation layer 115b and the adhesive layer AD (e.g., a first portion of an insulating layer in the first area A1) disposed between the first planarization layer 116a and the first light emitting diode ED1 in the first area A1 may be a first thickness T1, the thickness of the second passivation layer 115b, the adhesive layer AD, and the second planarization layer 116b (e.g., a second portion of an insulating layer in the second area A2) disposed between the first planarization layer 116a and the second light emitting diode ED2 in the second area A2 may be a second thickness T2, and the second thickness T2 may be thicker than the first thickness T1.

Meanwhile, the present disclosure is not limited thereto, and the second planarization layer 116b may be disposed on the same layer as the first light emitting diode ED1 and the second light emitting diode ED2, or the second planarization layer 116b may be disposed below the first light emitting diode ED1 and the second light emitting diode ED2. For example, the single insulating layer may be disposed between the first planarization layer 116a and the plurality of light emitting diodes ED. In this case, the insulating layer may be disposed to have different thicknesses in the first area A1 and the second area A2. For example, the insulating layer may have the first thickness in the first area A1 and the second thickness greater than the first thickness in the second area A2. Accordingly, the first light emitting diode ED1 may be disposed to be spaced apart from the top surface of the first planarization layer 116a as much as the first thickness, and the second light emitting diode ED2 may be disposed to be spaced apart from the top surface of the first planarization layer 116a as much as the second thickness.

The second planarization layer 116b may have the concave pattern CP in the second area A2. The concave pattern CP may be disposed in the area that overlaps the second light emitting diode ED2.

Referring to FIG. 3, the concave pattern CP may be disposed between the first electrode 134 and the second electrode 135 of the second red light emitting diode EDR2 in the second area A2. Accordingly, the first electrode 134 and the second electrode 135 may be disposed to be spaced apart from the top surface of the second planarization layer 116b in the concave pattern CP, but are not limited thereto.

In addition, the concave pattern CP may be disposed between the second connection electrode CE2 and the third connection electrode CE3 on a plane in a cross-section view of the display device. In addition, the plurality of bonding layers BDL may be disposed to overlap the second connection electrode CE2 and the third connection electrode CE3 with the concave pattern CP interposed therebetween. Accordingly, the plurality of bonding layers BDL may be disposed to be spaced apart from each other with the concave pattern CP interposed therebetween. Therefore, the concave pattern CP may suppress the short circuit defects in the second light emitting diode ED2, the short circuit defects in the plurality of bonding layers BDL, and the short circuit defects in the second connection electrode CE2 and the third connection electrode CE3.

Meanwhile, FIG. 3 illustrates that the second planarization layer 116b is disposed only in the area excluding the concave pattern CP in the second area A2, but is not limited thereto, and the second planarization layer 116b may be disposed to have a relatively thin thickness in the concave pattern CP and disposed to have a relatively thick thickness in the second area A2 excluding the concave pattern CP.

The first contact hole CH1 and the plurality of second contact holes CH2 may be disposed in the second planarization layer 116b to connect the plurality of connection electrodes CE to the plurality of reflective electrodes RE. Accordingly, the second planarization layer 116b may expose the top surfaces of the plurality of reflective electrodes RE in the first contact hole CH1 and the plurality of second contact holes CH2.

The third planarization layer 116c may cover the upper portions of the second planarization layer 116b and the first light emitting diode ED1 in the first area A1. Meanwhile, the contact hole through which the first and second electrodes of the first light emitting diode ED1 are exposed may be formed in the third planarization layer 116c. For example, referring to FIG. 3, the contact hole through which the first electrode 124 and the second electrode 125 of the first red light emitting diode EDR1 are exposed may be disposed in the third planarization layer 116c. The first electrode 124 and the second electrode 125 of the first red light emitting diode EDR1 may be exposed from the third planarization layer 116c, and the third planarization layer 116c may be partially disposed in the area between the first electrode 124 and the second electrode 125 to reduce the short circuit defects.

Meanwhile, the third planarization layer 116c may not be disposed in the second area A2. For example, the third planarization layer 116c may be disposed only in the area excluding second area A2 among the plurality of sub-pixels SP, but is not limited thereto.

The third planarization layer 116c may be configured by a single layer or a duplex layer, and may be formed of, for example, photoresist or an acrylic-based organic insulating material.

Meanwhile, FIG. 3 illustrates that the second planarization layer 116b and the third planarization layer 116c are disposed to surround the side surface portions of the plurality of first light emitting diodes ED1 in the first area A1, but are not limited thereto, and the second planarization layer 116b may be disposed to surround all the side surface portions of the plurality of first light emitting diodes ED1. In this case, the second planarization layer 116b may be disposed to have different thicknesses in the first area A1 and the second area A2. For example, the second planarization layer 116b may be disposed to have a thickness corresponding to the thickness of the plurality of first light emitting diodes ED1 in the first area A1 to surround the side surface portions of the plurality of first light emitting diodes ED1, but may be disposed to have a thickness thinner than that of the plurality of first light emitting diodes ED1 in the second area A2 to cover the top surface of the adhesive layer AD, but is not limited thereto.

The plurality of connection electrodes CE are disposed on the third planarization layer 116c. The plurality of connection electrodes CE may include the first connection electrode CE1, the second connection electrode CE2, and the third connection electrode CE3.

The first connection electrode CE1 may connect the plurality of first light emitting diode ED1 to the plurality of first reflective electrode RE1 in the first area A1. In addition, the first connection electrode CE1 may electrically connect the plurality of first light emitting diodes ED1 to the plurality of driving transistors DT.

The second connection electrode CE2 may electrically connect the second light emitting diode ED2 to the plurality of driving transistors DT in the second area A2.

The third connection electrode CE3 is connected to the plurality of first light emitting diode ED1 and the second light emitting diode ED2 in the first area A1 and the second area A2, and may be electrically connected to the second reflective electrode RE2. In addition, the third connection electrode CE3 may be electrically connected to the power line VL1 through the plurality of second contact holes CH2 formed in the second passivation layer 115b, the adhesive layer AD, and the second planarization layer 116b. Accordingly, the third connection electrode CE3 may electrically connect the power line VL1 to the first light emitting diode ED1 and the second light emitting diode ED2 in one sub-pixel SP.

Meanwhile, referring to FIG. 3, the second connection electrode CE2 and the third connection electrode CE3 may be disposed to be spaced apart from each other with the concave pattern CP interposed therebetween.

The plurality of connection electrodes CE may be formed of a transparent conductive material such as indium tin oxide (ITO) or indium zinc oxide (IZO), but is not limited thereto.

Meanwhile, in the drawings, the first connection electrode CE1 and the first reflective electrode RE1 are illustrated as being electrically connected to the source electrode SE of the driving transistor DT, but the third connection electrode CE3 and the second reflective electrode RE2 may be connected to the drain electrode DE of the driving transistor DT, but are not limited thereto.

Meanwhile, the plurality of connection electrodes CE may be disposed to have a step along the surface of the insulating layer disposed below the plurality of connection electrodes CE. For example, referring to FIG. 3, the first connection electrode CE1 may be disposed along the surface of the third planarization layer 116c in the first area A1, and the second connection electrode CE2 and the third connection electrode CE3 may be disposed along the surface of the second planarization layer 116c in the second area A2. Accordingly, a distance between the first connection electrode CE1 and the substrate 110 in the first area A1 may be longer than that between the second connection electrode CE2 and the third connection electrode CE3 and the substrate 110 in the second area A2.

In addition, the plurality of connection electrodes CE may cover the side surfaces of the second passivation layer 115b, the adhesive layer AD, and the second planarization layer 116b in the first contact hole CH1 and the plurality of second contact holes CH2. In this case, the second connection electrode CE2 and the third connection electrode CE3 may be disposed in a step shape along the surfaces of the second passivation layer 115b, the adhesive layer AD, and the second planarization layer 116b in the second area A2.

Referring to FIG. 3, the bank BB is disposed on the plurality of connection electrodes CE. The bank BB may be formed of opaque materials to reduce color mixing between the plurality of sub-pixels SP, and formed of, for example, a black resin, but is not limited thereto.

The bank BB may be disposed at a certain distance from the plurality of light emitting diodes ED, and may overlap at least a portion of the reflective electrode RE.

The bank BB may include an open area corresponding to the second area A2. The open area of the bank BB and the second light emitting diode ED2 may overlap. The bank BB may surround the side surface portions of the second light emitting diode ED2 in the second area A2.

Meanwhile, the open area of the bank BB may overlap the plurality of second contact holes CH2 to which the second light emitting diode ED2 and the plurality of reflective electrodes RE are connected. Accordingly, the bank BB may be disposed in the area excluding the plurality of second contact holes CH2 to which the second light emitting diode ED2 and the plurality of reflective electrodes RE are connected. For example, referring to FIG. 3, the bank BB may be disposed in the area excluding the plurality of second contact holes CH2 disposed on both sides of the second light emitting diode ED2. Accordingly, the bank BB may cover a portion of the second connection electrode CE2 and the third connection electrode CE3 disposed outside the plurality of second contact holes CH2.

Meanwhile, the present disclosure is not limited thereto, and the bank BB may cover a portion of the second connection electrode CE2 and the third connection electrode CE3 formed in the contact hole of the second passivation layer 115b and the adhesive layer AD.

In the second area A2, the plurality of bonding layers BDL are disposed above the plurality of connection electrodes CE. Referring to FIG. 3, the plurality of bonding layers BDL are disposed above the second connection electrode CE2 and the third connection electrode CE3. The bonding layer BDL includes a first portion between the second light emitting diode EDR2 and the second connection electrode CE2 and a second portion between the second light emitting diode EDR2 and the third connection electrode CE3 in the second area A2. The plurality of bonding layers BDL may fix (e.g., attach) the second light emitting diode ED2 on the substrate 110.

The plurality of bonding layers BDL may be disposed in the second area A2 of the plurality of sub-pixels SP. The plurality of bonding layers BDL are disposed on the second connection electrode CE2 and the third connection electrode CE3 exposed by the bank BB. Accordingly, the plurality of bonding layers BDL may be electrically connected to the top surfaces of the second connection electrode CE2 and the third connection electrode CE3 each disposed below the plurality of bonding layers BDL.

The plurality of bonding layers BDL may be disposed to overlap the second light emitting diode ED2 among the plurality of light emitting diodes ED. In this case, the bottom surfaces of the plurality of bonding layers BDL may be in contact with the second connection electrode CE2 and the third connection electrode CE3, and the top surfaces of the plurality of bonding layers BDL may be in contact with the first and second electrodes of the second light emitting diode ED2. For example, referring to FIG. 3, the top surfaces of the plurality of bonding layers BDL may be in contact with the first electrode 134 and the second electrode 135 of the second red light emitting diode EDR2. Accordingly, the plurality of bonding layers BDL may be connected to the second electrode and the second semiconductor layer of the second light emitting diode ED2 to electrically connect the second light emitting diode ED2 to the driving transistor DT, and electrically connect the second light emitting diode ED2 to the plurality of power lines VL1.

Meanwhile, FIG. 3 illustrates that the plurality of bonding layers BDL are non-overlapping with the concave pattern CP, but the plurality of bonding layers (BDL) may be disposed to overlap the concave pattern CP. For example, the plurality of bonding layers BDL extend from the top surfaces of the second connection electrode CE2 and the third connection electrode CE3 and may also be contact in the side surface of the second planarization layer 116b and the side surface of the adhesive layer AD surrounding the concave pattern CP. In addition, FIG. 3 illustrates that the plurality of bonding layers BDL are disposed to non-overlap with the plurality of second contact holes CH2, but the plurality of bonding layers BDL may extend from the second connection electrode CE2 and the third connection electrode CE3 to fill the plurality of second contact holes CH2.

The plurality of bonding layers BDL may be formed of a conductive material. In addition, the plurality of bonding layers BDL may be formed of a reflective material. For example, the plurality of bonding layers BDL may be formed of silver (Ag) or a silver (Ag) alloy, but are not limited thereto. In addition, the plurality of bonding layers BDL may be formed of any one of silver (Ag) paste, aluminum (Al) paste, gold (Au) paste, and copper (Cu) paste, and may be formed of silver (Ag), aluminum (Al), molybdenum (Mo), titanium (Ti), or an alloy thereof, but are not limited thereto.

Referring to FIGS. 2 and 3, the second light emitting diode ED2 is disposed on the plurality of bonding layers BDL.

The second light emitting diode ED2 is disposed in at least one sub-pixel SP among the plurality of sub-pixels SP. The second light emitting diode ED2 may be disposed in the second area A2 in the sub-pixel SP.

The second light emitting diode ED2 may include the first semiconductor layer, the light emitting layer, the second semiconductor layer, the first electrode, the second electrode, and the encapsulation film. For example, referring to FIG. 3 together, the second red light emitting diode EDR2 includes the first semiconductor layer 131, a light emitting layer 132, the second semiconductor layer 133, the first electrode 134, the second electrode 135, and an encapsulation film 136.

The second semiconductor layer 133 of the second red light emitting diode EDR2 is disposed on the second connection electrode CE2, the third connection electrode CE3, and the plurality of bonding layers BDL, and the first semiconductor layer 131 of the second red light emitting diode EDR2 is disposed on the second semiconductor layer 133. The first semiconductor layer 131 and the second semiconductor layer 133 may be layers formed by doping n-type and p-type impurities into a specific material. For example, the first semiconductor layer 131 and the second semiconductor layer 133 may each be layers doped with n-type and p-type impurities in materials such as gallium nitride (GaN), indium aluminum phosphide (InAlP), and gallium arsenide (GaAs). In addition, the p-type impurities may be magnesium, zinc (Zn), beryllium (Be), or the like, and the n-type impurities may be silicon (Si), germanium, tin (Sn), or the like, but is not limited thereto.

The light emitting layer 132 of the second red light emitting diode EDR2 is disposed between the first semiconductor layer 131 and the second semiconductor layer 133. The light emitting layer 132 may emit light by receiving holes and electrons from the first semiconductor layer 131 and the second semiconductor layer 133. The light emitting layer 132 may be formed of a single-layer or multi-quantum well (MQW) structure, and may be formed of, for example, indium gallium nitride (InGaN), gallium nitride (GaN), or the like, but is not limited thereto.

Meanwhile, the light emitting layer 132 and the second semiconductor layer 133 of the second red light emitting diode EDR2 may be disposed to protrude downward from the bottom surface of the first semiconductor layer 131.

The first electrode 134 of the second red light emitting diode EDR2 is disposed below the first semiconductor layer 131. The first electrode 134 is an electrode for electrically connecting the driving transistor DT to the first semiconductor layer 131. In this case, the first semiconductor layer 131 may be the semiconductor layer doped with n-type impurities, and the first electrode 134 may be a cathode.

The first electrode 134 may be formed of a conductive material, for example, a transparent conductive material such as indium tin oxide (ITO) or indium zinc oxide (IZO), an opaque conductive material such as titanium (Ti), gold (Au), silver (Ag), copper (Cu), an alloy thereof, or the like, but is not limited thereto.

The second electrode 135 of the second red light emitting diode EDR2 is disposed below the second semiconductor layer 133. The second electrode 135 may be in contact with the second semiconductor layer 133. The second electrode 135 is an electrode for electrically connecting the plurality of power lines VL1 to the second semiconductor layer 133.

The second electrode 135 may be formed of a conductive material, for example, a transparent conductive material such as indium tin oxide (ITO) or indium zinc oxide (IZO), an opaque conductive material such as titanium (Ti), gold (Au), silver (Ag), copper (Cu), an alloy thereof, or the like, but is not limited thereto.

Next, the encapsulation film 136 surrounding the first semiconductor layer 131, the light emitting layer 132, the second semiconductor layer 133, the first electrode 134, and the second electrode 135 is disposed. The encapsulation film 136 is formed of an insulating material and may protect the first semiconductor layer 131, the light emitting layer 132, and the second semiconductor layer 133. In addition, the contact hole is formed in the encapsulation film 136 to expose the first electrode 134 and the second electrode 135, so the plurality of bonding layers BDL and the first electrode 134 and the second electrode 135 may be electrically connected.

Meanwhile, the bottom surface of the second light emitting diode ED2 may be disposed at a higher position than the bottom surface of the plurality of first light emitting diodes ED1. For example, referring to FIG. 3, the first semiconductor layer 121 of the plurality of first red light emitting diode EDR1 may be disposed on the adhesive layer AD, and the first electrode 134 and the second electrode 135 of the second red light emitting diode EDR2 may be disposed on the second planarization layer 116b. Accordingly, the bottom surface of the second light emitting diode ED2 may be disposed at a higher position than the bottom surface of the first light emitting diode ED1 as much as the thickness of the second planarization layer 116b.

In addition, the first red light emitting diode EDR1 and the second red light emitting diode EDR2 have the same configuration as each other, but the stacking order of the second red light emitting diode EDR2 may be opposite to the stacking order of the first red light emitting diode EDR1. For example, the first red light emitting diode EDR1 may be a lateral light emitting diode, and the second red light emitting diode EDR2 may be a flip-chip light emitting diode. In addition, the first green light emitting diode EDG1 and the first blue light emitting diode EDB1 may be the lateral light emitting diodes, and the second green light emitting diode and the second blue light emitting diode may be the flip chip light emitting diodes.

The fourth planarization layer 117 is disposed on the plurality of connection electrodes CE and the bank BB. The fourth planarization layer 117 is a layer for protecting the components below the fourth planarization layer 117. The fourth planarization layer 117 may be configured by a single layer or a duplex layer, and may be formed of, for example, benzocyclobutene, light-transmissive epoxy, photoresist, or an acrylic-based organic material, but is not limited thereto.

The fourth planarization layer 117 may be disposed to overlap at least a portion of the plurality of light emitting diodes ED. For example, the fourth planarization layer 117 may be disposed in the first area A1 to overlap only the first light emitting diode ED1 among the plurality of light emitting diodes ED.

Meanwhile, the fourth planarization layer 117 may include the open area corresponding to the second area A2. The open area of the fourth planarization layer 117 may overlap the open area of the bank BB. For example, in the open area of the fourth planarization layer 117, the side surface of the fourth planarization layer 117 may be disposed on the same plane as the side surface of bank BB, but is not limited thereto. The protective layer 160 may be disposed above the fourth planarization layer 117.

The protective layer 160 may fill the open area of the fourth planarization layer 117 and the open area of bank BB in the second area A2, cover the second light emitting diode ED2 disposed in the second area A2, and fix and protect the second light emitting diode ED2. For example, the protective layer 160 may be formed of photoresist, an acrylic-based organic material, or light-transmissive epoxy, but is not limited thereto.

Referring to FIG. 3, an optical film MF covering the upper portion of the protective layer 160 is disposed on the entire upper area of the substrate 110. The optical film MF may be a functional film implementing a higher-definition image while protecting the display device 100. For example, the optical film (MF) may include an anti-scattering film, an anti-glare film, an anti-reflecting film, a low-reflecting film, a brightness enhancement film (OLED transmittance controllable film), a polarizer, etc., but is not limited thereto.

Meanwhile, an adhesive portion may be disposed between the protective layer 160 and the optical film MF above the substrate 110. The adhesive portion may be formed on the front surface of the substrate 110 to bond between the protective layer 160 and the optical film MF. The adhesive portion may be formed of a photocurable adhesive material that may be cured by light. For example, the adhesive portion may be formed of an acrylic-based material containing a photosensitizer, but is not limited thereto.

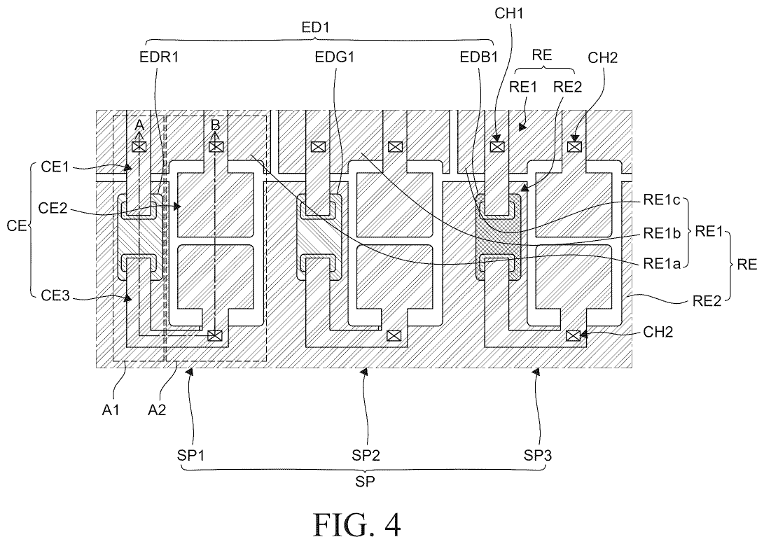

FIG. 4 is an enlarged plan view of a display device before a repair process according to an exemplary embodiment of the present disclosure.

Referring to FIG. 4, each sub-pixel SP has the plurality of first light emitting diodes ED1 disposed in the first area A1. For example, the first red light emitting diode EDR1 may be disposed in the first sub-pixel SP1, the first green light emitting diode EDG1 may be disposed in the second sub-pixel SP2, and the first blue light emitting diode EDB1 may be disposed in the third sub-pixel SP3. On the other hand, the second light emitting diode ED2 is not disposed in the second area A2.

The plurality of connection electrodes CE are disposed above the first light emitting diode ED1 in the first area A1.

Among the plurality of connection electrodes CE, the second connection electrode CE2 and the third connection electrode CE3 cover the upper portion of the second area A2 where the second light emitting diode ED2 is not disposed.

Thereafter, a lighting inspection may be performed on the plurality of first light emitting diodes ED1 disposed in the first area A1 of the plurality of sub-pixels SP.

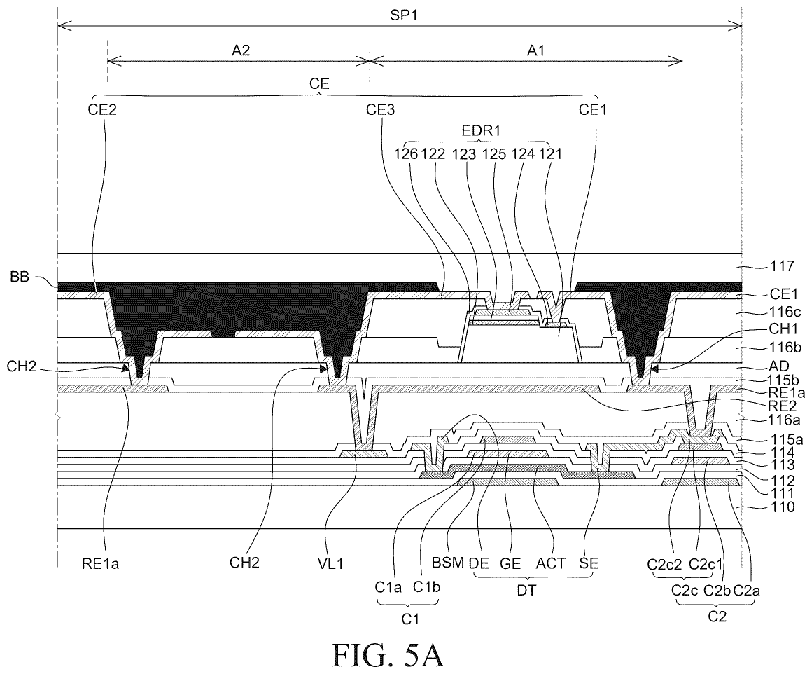

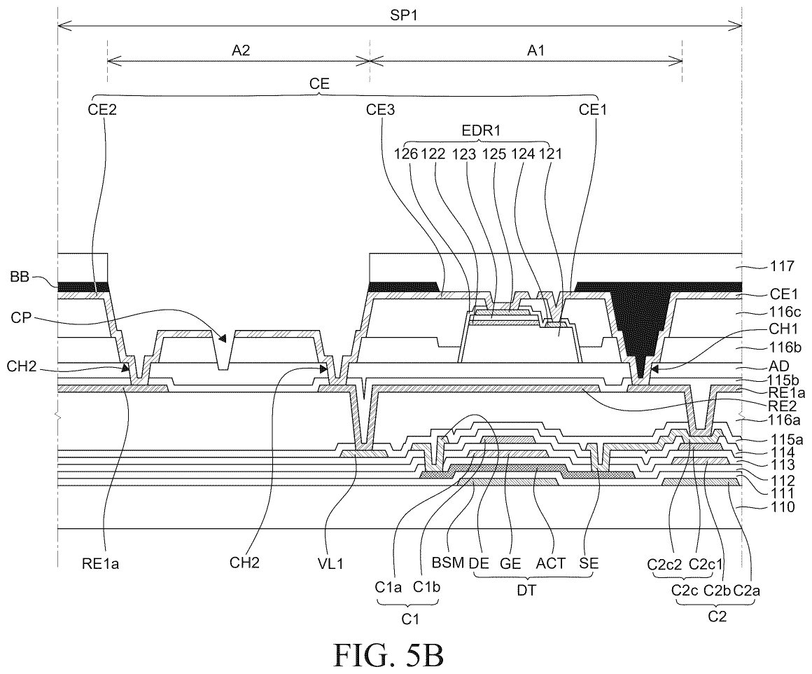

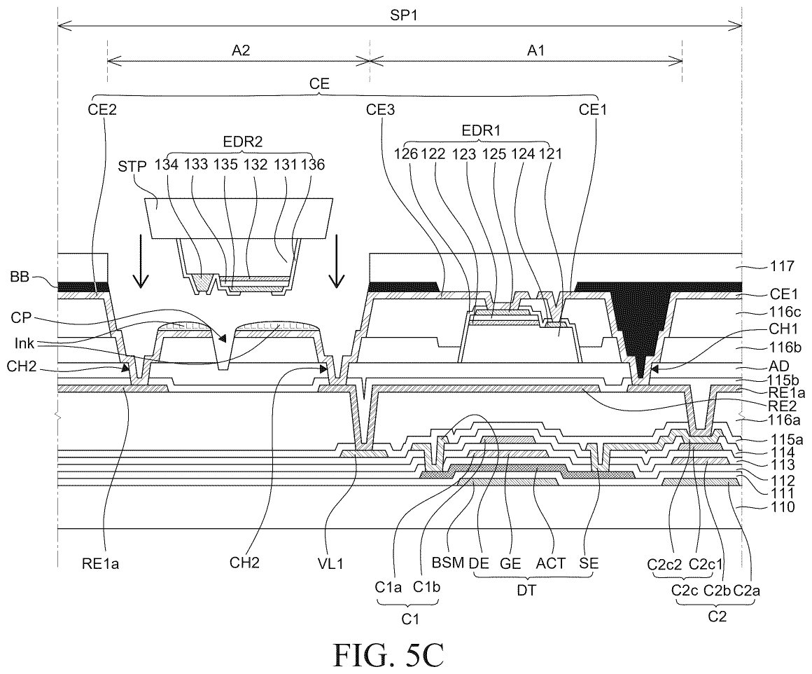

FIGS. 5A to 5C are diagrams for describing a repair process of a display device according to an exemplary embodiment of the present disclosure.

Referring to FIG. 5A, the plurality of first light emitting diodes ED1 are disposed in the first area A1 of each sub-pixel SP, while no second light emitting diode ED2 is disposed in the second area A2.

The plurality of connection electrodes CE are disposed above the plurality of first light emitting diodes ED1 in the first area A1. The first connection electrode CE1 and the third connection electrode CE3 among the plurality of connection electrodes CE are disposed above the plurality of first light emitting diodes ED1 in the first area A1, and the second connection electrode CE2 and the third connection electrode CE3 cover the upper portion of the second planarization layer 116b in the second area A2. That is, the second connection electrode CE2 and the third connection electrode CE3 in the second area A2 are in contact with the upper surface of the second planarization layer 116b. As shown in FIG. 5A, the third connection electrode CE3 includes a first portion that is connected to the second electrode 125 in the first area A1 and a second portion that is in the second area A2 at a height that is less than a height of the first portion of the third connection electrode CE3 in the first area A1.

Meanwhile, the second planarization layer 116b is disposed to have a flat top surface in an area excluding the plurality of second contact holes CH2 in the second area A2. Accordingly, in the second area A2, the top surface of the second planarization layer 116b and the bottom surfaces of the second connection electrode CE2 and the third connection electrode CE3 are disposed on the same plane.

The bank BB and the fourth planarization layer 117 are sequentially disposed on the plurality of connection electrodes CE. As shown in FIG. 5A, the bank BB is within the first contact hole CH1 in the first area A1 and within the second contact hole CH2 in the second area A2. The structure shown in FIG. 5A is representative of a normally functioning first light emitting diode ED1. That is, the first red light emitting diode EDR1 is not defective.

However, the lighting inspection may be performed on the plurality of first light emitting diodes ED1 disposed in the first area A1 of the plurality of sub-pixels SP, and the repair may be performed on the sub-pixel SP where defects occur. As described above, the case will be described where since, among the plurality of sub-pixels SP, the first red light emitting diode EDR1 disposed in the first sub-pixel SP1 is defective and the first green light emitting diode EDG1 disposed in the second sub-pixel SP2 and the first blue light emitting diode EDB1 disposed in the third sub-pixel SP3 are normal, the repair process is performed on the first sub-pixel SP1.

Referring to FIG. 5B, the bank BB and the fourth planarization layer 117 are removed from the second area A2 of the sub-pixel SP where defects have occurred. For example, the bank BB and the fourth planarization layer 117 disposed in second area A2 are removed through the laser process. In this case, the laser process may be performed on a width greater than the width of the second red light emitting diode EDR2 to be disposed in the second area A2. In addition, the laser process may expose a portion of the top surfaces of the second connection electrode CE2 and the third connection electrode CE3 corresponding to the area of the second red light emitting diode EDR2, and expose the top surfaces of the second connection electrode CE2 and the third connection electrode CE3 overlapping the plurality of second contact holes CH2.

In this case, a portion of the second planarization layer 116b and the adhesive layer AD exposed between the second connection electrode CE2 and the third connection electrode CE3 are removed. Accordingly, the concave pattern CP disposed between the second connection electrode CE2 and the third connection electrode CE3 is formed in the second planarization layer 116b and the adhesive layer AD.

Next, referring to FIG. 5C, liquid metal ink is applied on the exposed second connection electrode CE2 and third connection electrode CE3. The liquid metal ink may be a solution in which metal nanoparticles are dispersed. The liquid metal ink may be, for example, one of metal organic ion ink, metal nanoparticle ink, and metal nanoparticle paste. When the liquid metal ink is silver (Ag) paste, it may be a solution in which silver (Ag) nanoparticles are evenly dispersed in an organic solvent.

Next, the second red light emitting diode EDR2, which is the repair light emitting diode, is transferred onto the liquid metal ink. The second red light emitting diode EDR2 may be transferred locally using a stamp STP, but is not limited thereto.

The second semiconductor layer 133 of the second red light emitting diode EDR2 is disposed below the first semiconductor layer 131. In this case, the second electrode 135 of the second red light emitting diode EDR2 is in contact with the liquid metal ink disposed above the third connection electrode CE3, and the first electrode 134 of the second red light emitting diode EDR2 is in contact with the liquid metal ink disposed above the second connection electrode CE2.

Thereafter, a sintering process is performed on the liquid metal ink. During the sintering process, the solvent contained in the liquid metal ink is volatilized. Accordingly, after the sintering process, the plurality of bonding layers BDL may be formed on the second connection electrode CE2 and the third connection electrode CE3, and the first electrode 134 of the second red light emitting diode EDR2 and the second connection electrode CE2 may be electrically connected, and the second electrode 135 of the second red light emitting diode EDR2 and the third connection electrode CE3 may be electrically connected.

Thereafter, the protective layer 160 may be applied on the upper portion of the second red light emitting diode EDR2 to surround the side surface of the second red light emitting diode EDR2 and the side surface of the bank BB.

In general, in the plurality of sub-pixels disposed on the substrate, the defective sub-pixels that do not emit light normally may occur. For example, the defective sub-pixel may occur in which the light emitting diode itself is defective or the electrical connection between the light emitting diode and the transistor and power line is defective. In this case, the defective sub-pixel is not lit or even if the defective sub-pixel emits light, the defective sub-pixel emits light very weakly, making it difficult to be used as the normal sub-pixel. Accordingly, in the display device, after the lighting inspection, the second light emitting diode that emits the same color as the first light emitting diode is transferred to the subpixels emitted by the defective first light emitting diode. For example, after the lighting inspection, the laser process is performed to perform the repair locally. In the repair process, the bank is opened in the second area of the sub-pixel requiring the repair, the plurality of connection electrodes are exposed, and the second light emitting diode is transferred onto the plurality of connection electrodes.

However, it may be difficult to accurately transfer the second light emitting diode in the repair area. For example, when the repair is performed locally using the laser process, the process errors may occur and it may be difficult to precisely transfer the second light emitting diode to the repair location. For example, when transferring the second light emitting diode by removing the insulating layer including the bank, as the moving distance corresponding to the thickness of the insulating layer increases, the alignment error may increase or the second light emitting diode may be biased or tilted. Accordingly, the contact defects may occur between the plurality of connection electrodes and the second light emitting diode, or the short circuit defects may occur between the plurality of connection electrodes and the electrodes of the second light emitting diode.

Accordingly, in the display device 100 according to the exemplary embodiment of the present disclosure, the second light emitting diode ED2 is disposed to protrude above the plurality of first light emitting diodes ED1 in the second area A2. For example, the insulating layer disposed on the first planarization layer 116a is disposed with the thicker thickness in the second area A2 than in the first area A1. Accordingly, the top surface of the second connection electrode CE2 and the third connection electrode CE3 may be disposed above the bottom surface of the first light emitting diode ED1. Therefore, by reducing the moving distance of the second light emitting diode ED2 during the repair process, the transfer position may be easily controlled. Accordingly, the second connection electrode CE2 and the third connection electrode CE3 and the second light emitting diode ED2 may be easily bonded, and the problem of the deterioration in the electrical contact properties due to the bias or tilt of the second light emitting diode ED2 may be improved. Therefore, the second light emitting diode ED2 may be stably fixed to the second area A2, and the reliability of the repair process may be improved.

In addition, in the display device 100 according to an exemplary embodiment of the present disclosure, the plurality of second contact holes CH2 disposed in the second area A2 are disposed at both ends of the bonding layer BDL. In addition, the plurality of second contact holes CH2 are disposed at both ends of the second light emitting diode ED2, and the second planarization layer 116b and the adhesive layer AD in the plurality of second contact holes CH2 may form the step structure. Accordingly, when the bonding layer BDL overflows in the second area A2, the bonding layer BDL may move to the plurality of second contact holes CH2. Accordingly, the plurality of bonding layers BDL may be suppressed from moving to the center of the second area A2, and the plurality of bonding layers BDL may be suppressed from being connected to each other. Accordingly, in the display device 100 according to an exemplary embodiment of the present disclosure, the short circuit defects of the second connection electrode CE2 and third connection electrode CE3 and the short circuit defects of the second light emitting diode ED2 may be suppressed.

In addition, in the display device 100 according to an exemplary embodiment of the present disclosure, the concave pattern CP is disposed between the second connection electrode CE2 and the third connection electrode CE3 in the second area A2. Accordingly, when the bonding layer BDL overflows, the bonding layer BDL may move in the direction in which the concave pattern CP is disposed and may move to the step area of the concave pattern CP. Accordingly, the plurality of bonding layers BDL may be disconnected between the second connection electrode CE2 and the third connection electrode CE3. Accordingly, the concave pattern CP may suppress the plurality of bonding layers BDL from being connected to each other, and suppress the short circuit of the second connection electrode CE2 and third connection electrode CE3 and the short circuit of the second light emitting diode.

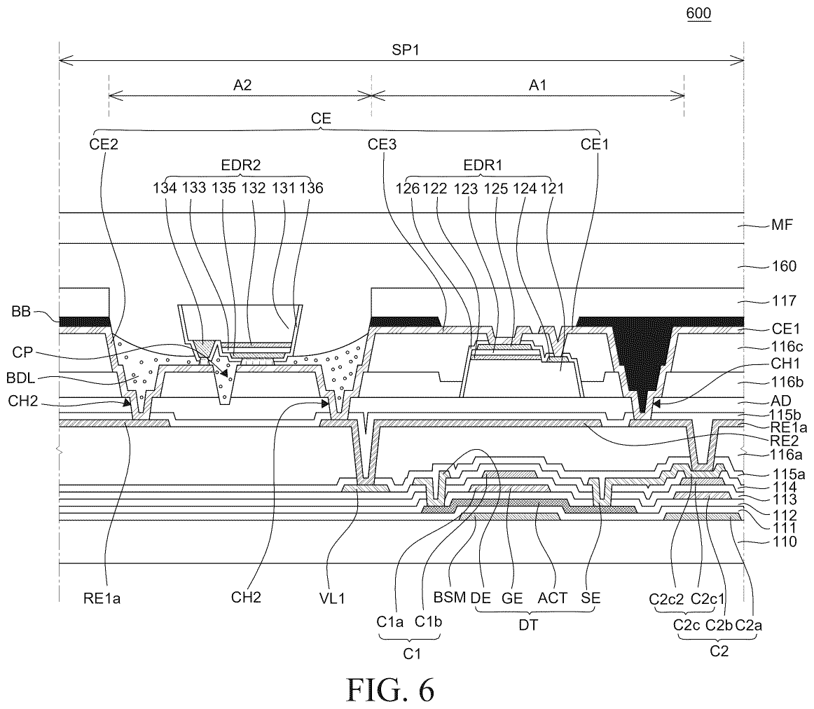

FIG. 6 is a cross-sectional view of a display device according to another exemplary embodiment of the present disclosure. The display device 600 of FIG. 6 is different from the display device 100 of FIGS. 1 to 5c only in the bonding layer BDL and other components are substantially the same, and therefore, redundant descriptions thereof will be omitted.

Referring to FIG. 6, the plurality of bonding layers BDL are disposed above the second connection electrode CE2 and the third connection electrode CE3 in the second area A2. The plurality of bonding layers BDL may fix the second light emitting diode ED2 on the substrate 110.

The plurality of bonding layers BDL may be formed of a conductive material. For example, the plurality of bonding layers BDL may be formed of anisotropic conductive paste ACP including conductive balls. For example, the plurality of bonding layers BDL may be an insulating layer in which the conductive balls are dispersed, and the conductive balls may be attached to the lower portions of the first electrode and the second electrode of the second light emitting diode ED2 to electrically connect the second connection electrode CE2 and the third connection electrode CE3 to the second light emitting diode ED2.

Accordingly, in a display device 600 according to another exemplary embodiment of the present disclosure, the second light emitting diode ED2 is disposed to protrude above the plurality of first light emitting diodes ED1 in the second area A2. Accordingly, the second connection electrode CE2 and the third connection electrode CE3 and the second light emitting diode ED2 may be easily bonded and the second light emitting diode ED2 may be stably fixed to the second area A2, so the reliability of the repair process may be stably improved.

In addition, in the display device 600 according to another exemplary embodiment of the present disclosure, the plurality of second contact holes CH2 disposed in the second area A2 may be disposed at both ends of the bonding layer BDL, so the overflowing bonding layer BDL may move to the plurality of second contact holes CH2. Accordingly, the short circuit defects of the second connection electrode CE2 and third connection electrode CE3 and the short circuit defects of the second light emitting diode ED2 may be suppressed.

In addition, in the display device 600 according to another exemplary embodiment of the present disclosure, the concave pattern CP is disposed between the second connection electrode CE2 and the third connection electrode CE3 in the second area A2. Accordingly, the concave pattern CP may suppress the plurality of bonding layers BDL from being connected to each other. For example, in the process of attaching the light emitting diode to the ACP, the conductive balls of the ACP may be connected to each other due to heat and/or pressure, resulting in the short circuit. Accordingly, in the display device 600 according to another exemplary embodiment of the present disclosure, the concave pattern CP may suppress the plurality of bonding layers BDL from being connected to each other, and suppress the second connection electrode CE2 and the third connection electrode CE3 from being short-circuited and the second light emitting diode ED2 from being short-circuited.

The exemplary embodiments of the present disclosure can also be described as follows:

According to an aspect of the present disclosure, there is provided a display device. The display device comprises a substrate on which a plurality of sub-pixels each including a first area and a second area is defined. The display device comprises a plurality of reflective electrodes disposed on the substrate. The display device comprises a plurality of transistors disposed in each of the plurality of sub-pixels on the substrate. The display device comprises a plurality of first light emitting diodes each disposed in the first area in the plurality of sub-pixels. The display device comprises at least one second light emitting diode disposed in the second area in at least one of the plurality of sub-pixels and including at least one second light emitting diode different from the plurality of first light emitting diodes, wherein a bottom surface of the second light emitting diode and bottom surfaces of the plurality of first light emitting diodes are disposed on different planes.

The bottom surface of the second light emitting diode may be disposed at a higher position than the bottom surfaces of the plurality of first light emitting diodes.

The display device may further comprise an insulating layer disposed on the substrate, and a bank disposed on the insulating layer, wherein the insulating layer, may include a plurality of contact holes through which the second light emitting diode and the plurality of reflective electrodes may be connected, and the bank may be disposed in an area excluding the plurality of contact holes.

The display device may further comprise a planarization layer planarizing an upper portion of the plurality of transistors, and an insulating layer disposed below the planarization layer and the plurality of first light emitting diodes and the second light emitting diode, wherein a thickness of the insulating layer may be different in the first area and the second area.

The thickness of the insulating layer may have a first thickness in the first area and a second thickness greater than the first thickness in the second area.

In the second area, the insulating layer may include a concave pattern, and in the concave pattern, the thickness of the insulating layer may be thinner than the second thickness.

The concave pattern may overlap the second light emitting diode.

The display device may further comprise a connection electrode electrically connecting the plurality of first light emitting diodes and the second light emitting diode to the plurality of transistors, wherein the connection electrode may be disposed on the plurality of first light emitting diodes in the first area, and may be disposed below the second light emitting diode in the second area.

The plurality of first light emitting diodes and the second light emitting diode each may include a first semiconductor layer, a second semiconductor layer having a width smaller than that of the first semiconductor layer, a light emitting layer having a width smaller than that of the first semiconductor layer and disposed between the first semiconductor layer and the second semiconductor layer, a first electrode in contact with the first semiconductor layer, and a second electrode in contact with the second semiconductor layer, wherein a stacking order of the plurality of first light emitting diodes and the second light emitting diode may be reversed.

The plurality of reflective electrodes may include the plurality of first reflective electrodes, and a second reflective electrode disposed to be spaced apart from the plurality of first reflective electrodes and disposed to overlap the plurality of first light emitting diodes. The connection electrode may include a first connection electrode connecting the plurality of first light emitting diodes and the plurality of first reflective electrodes. The connection electrode may include a second connection electrode connecting the second light emitting diode and the plurality of first reflective electrodes. The connection electrode may include a third connection electrode connecting the plurality of first light emitting diodes and the second light emitting diode and connected to the first reflective electrode.

The display device may further comprise a bonding layer disposed between the second light emitting diode and the second connection electrode and between the second light emitting diode and the third connection electrode.

The display device may further comprise an insulating layer disposed below the second connection electrode and the third connection electrode, wherein the insulating layer may include a concave pattern disposed between the second connection electrode and the third connection electrode.

The bonding layer may be formed of silver (Ag) paste.

The bonding layer may be formed of anisotropic conductive paste (ACP).

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate;
a plurality of sub-pixels on the substrate, each sub-pixel including a first area and a second area;
a plurality of reflective electrodes on the substrate;
a plurality of transistors in each of the plurality of sub-pixels on the substrate;
a plurality of first light emitting diodes, each first light emitting diode in the first area of a corresponding sub-pixel of the plurality of sub-pixels; and
a second light emitting diode in the second area of at least one sub-pixel of the plurality of sub-pixels,
wherein the second light emitting diode is different from the plurality of first light emitting diodes, and a bottom surface of the second light emitting diode and bottom surfaces of the plurality of first light emitting diodes are on different planes in a cross-section view of the display device.

2. The display device of claim 1, wherein the bottom surface of the second light emitting diode is at a height with respect to the substrate that is higher than a height of the bottom surfaces of the plurality of first light emitting diodes.

3. The display device of claim 1, further comprising:
an insulating layer on the substrate;
a bank on the insulating layer; and
a plurality of contact holes in the insulating layer through which the second light
emitting diode and the plurality of reflective electrodes are connected, wherein the bank is non-overlapping with the plurality of contact holes.

4. The display device of claim 1, further comprising:
a planarization layer on an upper portion of the plurality of transistors; and
an insulating layer above the planarization layer, below the plurality of first light emitting diodes, and the second light emitting diode,
wherein a thickness of a first portion of the insulating layer in the first area is different from a thickness of a second portion of the insulating layer in the second area.

5. The display device of claim 4, wherein the thickness of the first portion of the insulating layer in the first area is less than the thickness of the second portion of the insulating layer in the second area.

6. The display device of claim 5, wherein the second portion of the insulating layer in the second area includes a concave pattern through the second portion of the insulating layer, and a depth of the concave pattern is less than the thickness of the second portion of the insulating layer in the second area.

7. The display device of claim 6, wherein the concave pattern overlaps the second light emitting diode in the second area.

8. The display device of claim 1, further comprising:
a connection electrode electrically connecting the plurality of first light emitting diodes and the second light emitting diode to the plurality of transistors,
wherein the connection electrode is above and overlaps the plurality of first light emitting diodes in the first area, and the connection electrode overlaps and is below the second light emitting diode in the second area.

9. The display device of claim 8, wherein the plurality of first light emitting diodes and the second light emitting diode each include a plurality of layers including:
a first semiconductor layer;
a second semiconductor layer having a width that is smaller than a width of the first semiconductor layer;
a light emitting layer having a width that is smaller than the width of the first semiconductor layer, the light emitting layer between the first semiconductor layer and the second semiconductor layer;
a first electrode in contact with the first semiconductor layer; and
a second electrode in contact with the second semiconductor layer,
wherein a stacking order of the plurality of layers of the plurality of first light emitting diodes is reversed from a stacking order of the plurality of layers of the second light emitting diode.

10. The display device of claim 8, wherein the plurality of reflective electrodes include:
a plurality of first reflective electrodes; and
a second reflective electrode spaced apart from the plurality of first reflective electrodes and on a same plane as the plurality of first reflective electrodes, the second reflective electrode overlapping the plurality of first light emitting diodes in the first area,
wherein the connection electrode includes:
a first connection electrode connected to the plurality of first light emitting diodes and the plurality of first reflective electrodes;
a second connection electrode connected to the second light emitting diode and the plurality of first reflective electrodes; and
a third connection electrode connected to the plurality of first light emitting diodes, the second light emitting diode, and the second reflective electrode.

11. The display device of claim 10, further comprising:
a bonding layer including a first portion between the second light emitting diode and the second connection electrode and a second portion between the second light emitting diode and the third connection electrode in the second area.

12. The display device of claim 11, further comprising:
an insulating layer below a portion of the second connection electrode and a portion of the third connection electrode, the insulating layer including a concave pattern between the portion of the second connection electrode and the portion of the third connection electrode.

13. The display device of claim 11, wherein the bonding layer includes silver paste.

14. The display device of claim 11, wherein the bonding layer includes anisotropic conductive paste.

15. A display device, comprising:
a substrate;
a sub-pixel on the substrate, the sub-pixel including a first area and a second area that is spaced apart from the first area;
a transistor on the substrate;
a light emitting diode in the first area, the light emitting diode including a first electrode and a second electrode;
a first connection electrode connected to the first electrode of the light emitting diode in the first area, the first connection electrode electrically connecting the first electrode and the transistor;
an additional connection electrode including a first portion of the additional connection electrode that is connected to the second electrode in the first area and a second portion that is in the second area at a height that is less than a height of the first portion of the additional connection electrode in the first area, the additional connection electrode electrically connecting together the second electrode of the light emitting diode and a power line; and
a bank including a first portion of the bank in the first area, a second portion of the bank that is on the second portion of the additional connection electrode in the second area, and an opening overlapping the light emitting diode in the first area.

16. The display device of claim 15, further comprising:
a planarization layer in the first area and the second area, the planarization layer on the transistor in the first area;
a first reflective electrode on the planarization layer, the first reflective electrode connected to the first connection electrode in the first area and connected to the transistor; and
a second reflective electrode on the planarization layer and on a same plane as the first reflective electrode, the second reflective electrode connected to the second connection electrode in the second area.

17. The display device of claim 16, further comprising:
an insulating layer including a first portion of the insulating layer that is between the light emitting diode and the second reflective electrode in the first area and a second portion of the insulating layer that is overlapped by the second portion of the additional connection electrode in the second area,
wherein a thickness of the second portion of the insulating layer in the second area is greater than a thickness of the first portion of the insulating layer in the first area.

18. The display device of claim 17, wherein the second portion of the additional connection electrode in the second area is in contact with an upper surface of the second portion of the insulating layer in the second area.

19. The display device of claim 18, further comprising:
a second connection electrode that is in contact with the upper surface of the second portion of the insulating layer in the second area, the second connection electrode spaced apart from the additional connection electrode on the upper surface of the second portion of the insulating layer.

20. The display device of claim 17, further comprising:
a first contact hole through the first portion of the insulating layer in the first area, the first connection electrode connected to the first reflective electrode through the first contact hole; and
a second contact hole through the second portion of the insulating layer in the second area, the additional connection electrode connected to the second reflective electrode through the second contact hole.

21. The display device of claim 20, wherein the first portion of the bank is within the first contact hole and the second portion of the bank is within the second contact hole.

22. The display device of claim 15, wherein the light emitting diode includes:
a first semiconductor layer including a first portion of the first semiconductor layer and a second portion of the first semiconductor layer;
a second semiconductor layer overlapping the first portion of the first semiconductor layer without overlapping the second portion of the first semiconductor layer;
a light emitting layer between the second semiconductor layer and the first portion of the first semiconductor layer,
wherein the first electrode is on the second portion of the first semiconductor layer and the second electrode is on the second semiconductor layer.

23. The display device of claim 22, wherein a portion of the first connection electrode that is connected to the first electrode is over the light emitting diode and a portion of the additional connection electrode that is connected to the second electrode is over the light emitting diode.

24. The display device of claim 15, wherein the second portion of the additional connection electrode in the second area is configured to connect to another light emitting diode in the second area but the second area lacks the other light emitting diode.
